(19) United States
(12) Patent Application Publication
(10) Pub. No.: US 2009/0097211 A1
(43) Pub. Date: Apr. 16, 2009

(54) CIRCUIT MODULE AND CIRCUIT BOARD ASSEMBLY HAVING SIP CONNECTOR

(75) Inventors: Tsu-Cheng Chen, Taoyuan (TW); Chih-Hung Chiang, Taoyuan (TW); Kai-Hung Huang, Taoyuan (TW); Yi-Hwa Hsieh, Taoyuan (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/035,524

(22) Filed: Feb. 22, 2008

(30) Foreign Application Priority Data
Oct. 15, 2007 (TW) 096138499

(51) Int. Cl. H05K 1/14

(52) U.S. Cl. 361/740; 361/742

(57) ABSTRACT

A circuit module to be mounted on a system board having multiple through holes is disclosed. The circuit module includes a circuit board, multiple SIP connectors and multiple sheathing elements. Each of the SIP connectors includes a connecting part disposed at a first end thereof and fixed on the circuit board and an insertion part disposed at a second end thereof. Each of the sheathing elements includes a plurality of clamping arms and a receiving portion. The receiving portion is defined by the clamping arms for receiving the insertion part of a corresponding SIP connector. The insertion part is clamped by the clamping arms such that the sheathing element is fixed on the SIP connector. The sheathing element is sustained against a surface of the system board after the insertion part is inserted into a corresponding through hole of the system board, so that the support area between the SIP connector and the system board is increased.

### FIELD OF THE INVENTION

The present invention relates to a circuit module and a circuit board assembly having a connector, and more particularly to a circuit module and a circuit board assembly having a SIP connector.

### BACKGROUND OF THE INVENTION

Conventionally, two approaches are used to mount a subsidiary daughter board to a system board. In the first approach, the daughter board and the system board are electrically connected with each other via a surface-mount connector according to a surface mount technology (SMT). In the second approach, a plurality of SIP (single in-line package) connectors or conductive pins are firstly mounted on the daughter board, then inserted into predetermined though holes of a system board and finally soldered on the system board through solder paste. Since the sidewalls of the though holes are coated with conductive material, the daughter board is electrically connected to the system board via these SIP connectors. The second approach is also referred as a pin-through-hole technology (PTHT).

The conventional pin-through-hole technology, however, still has some drawbacks. For example, if different system boards with different sizes are used, the diameters of the through holes may be varied. For inserting the SIP connectors into corresponding through holes and allowing the SIP connectors to be sustained against the surface of the system board, the outer diameter of the SIP connector needs to be changed. Once the outer diameter of the SIP connector is changed, the layout configuration of the daughter board needs to be changed and the fabricating cost of changing the SIP connector will be increased.

Moreover, if the diameter of the through hole is greater than the outer diameter of the SIP connector, the SIP connector may fail to be sustained against the surface of the system board. In this circumstance, some SIP connectors are usually not coplanar and thus suffered from poor solderability after the soldering process. Therefore, the electrical connection and the structural stability between the daughter board and the system board are impaired, and the product yield is reduced.

Therefore, there is a need of providing a circuit module and a circuit board assembly having a general-purpose SIP connector in order to simplify the fabricating process, save cost and avoid poor solderability.

### SUMMARY OF THE INVENTION

It is an object of the present invention to provide a circuit module and a circuit board assembly having a general-purpose SIP connector. By pairing a sheathing element with of the SIP connector, the support area between the SIP connector and the system board is increased and the electrical connection and the structural stability between the daughter board and the system board are enhanced. Even if the diameter of the through hole in the system board is changed, the SIP connector will be sustained against the surface of the system board in the assistance of the sheathing element.

In accordance with an aspect of the present invention, there is provided a circuit module to be mounted on a system board having multiple through holes. The circuit module includes a circuit board, multiple SIP connectors and multiple sheathing elements. Each of the SIP connectors includes a connecting part disposed at a first end thereof and fixed on the circuit board and an insertion part disposed at a second end thereof. Each of the sheathing elements includes a plurality of clamping arms and a receiving portion. The receiving portion is defined by the clamping arms for receiving the insertion part of a corresponding SIP connector. The insertion part is clamped by the clamping arms such that the sheathing element is fixed on the SIP connector. The sheathing element is sustained against a surface of the system board after the insertion part is inserted into a corresponding through hole of the system board, so that the support area between the SIP connector and the system board is increased.

In accordance with another aspect of the present invention, there is provided a circuit board assembly. The circuit board assembly includes a first circuit board, a second circuit board having a plurality of through holes, multiple SIP connectors and multiple sheathing elements. The SIP connectors are arranged between the first circuit board and the second circuit board. Each of the SIP connectors includes a connecting part disposed at a first end thereof and fixed on the first circuit board and an insertion part disposed at a second end thereof. Each of the sheathing elements includes a plurality of clamping arms and a receiving portion. The receiving portion is defined by the clamping arms for receiving the insertion part of a corresponding SIP connector. The insertion part is clamped by the clamping arms such that the sheathing element is fixed on the SIP connector. The sheathing element is sustained against a surface of the second circuit board after the insertion part is inserted into a corresponding through hole of the second circuit board, so that the support area between the SIP connector and the second circuit board is increased and the first circuit board is electrically and structurally connected with the second circuit board via the SIP connector.

In accordance with another aspect of the present invention, there is provided a sheathing element to be sheathed around a SIP connector. The SIP connector is inserted into a through hole of a circuit board. The sheathing element includes a plurality of clamping arms and a receiving portion. The receiving portion is defined by the clamping arms for receiving the SIP connector. The sheathing element is sustained against a surface of the circuit board after an insertion part of the SIP connector is inserted into the through hole of the circuit board, so that the support area between the SIP connector and the circuit board is increased.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic view illustrating a circuit module according to a first preferred embodiment of the present invention;

FIG. 1B is a schematic perspective view of a sheathing element shown in FIG. 1A;

FIG. 1C is a schematic assembled view of the circuit module shown in FIG. 1A;

FIG. 2 is a schematic perspective view of a circuit board assembly including the circuit module of FIG. 1C;

FIG. 3A is a schematic view illustrating a circuit module according to a second preferred embodiment of the present invention;

FIG. 3B is a schematic perspective view of a sheathing element shown in FIG. 3A;

FIG. 4A is a schematic view illustrating a circuit module according to a third preferred embodiment of the present invention;

FIG. 4B is a schematic perspective view of a sheathing element shown in FIG. 4A;

FIG. 5 is a schematic view illustrating a circuit module according to a fourth preferred embodiment of the present invention; and

FIG. 6 is a schematic view illustrating a circuit module according to a fifth preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

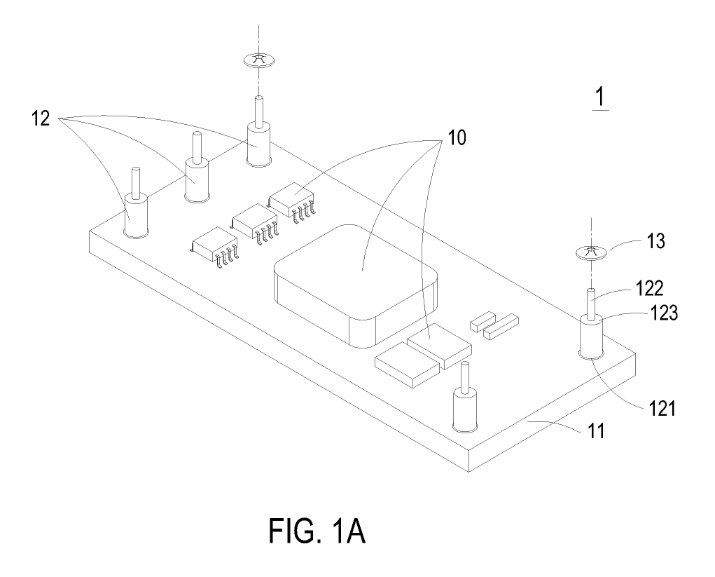

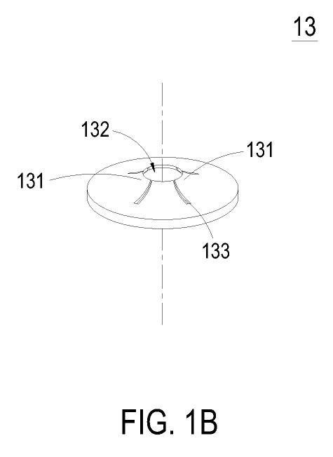

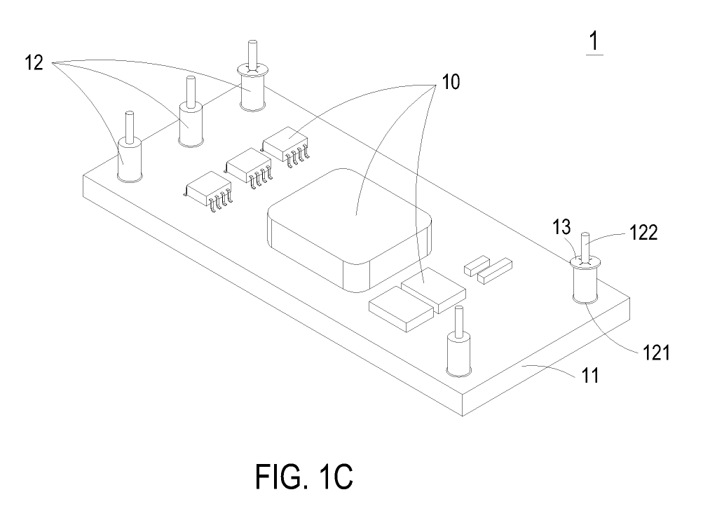

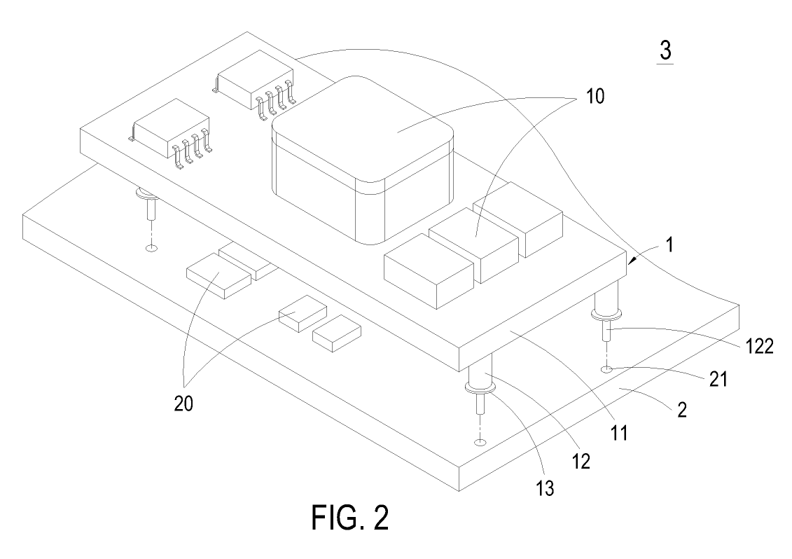

FIG. 1A is a schematic view illustrating a circuit module according to a first preferred embodiment of the present invention. As shown in FIG. 1A, the circuit module 1 principally includes a first circuit board 11, multiple SIP connectors 12 and multiple sheathing elements 13. Several electronic components 10 and the SIP connectors 12 are mounted on the first circuit board 11. Each SIP connector 12 principally includes a connecting part 121, an insertion part 122 and an intermediate part 123. The intermediate part 123 is substantially a cylindrical rod, which is perpendicular to the surface of the first circuit board 11 and made of conductive material (e.g. metallic material). The connecting part 121 is disposed at one end of the SIP connector 12. The SIP connector 12 is fixed on the first circuit board 11 by applying solder paste onto the connecting part 121 and a corresponding soldering pad (not shown) of the first circuit board 11 according to a surface mount technology. Alternatively, the SIP connector 12 may be fixed on the first circuit board 11 by inserting the connecting part 121 into a corresponding through hole (not shown) of the first circuit board 11 according to a pin-through-hole technology. The insertion part 122 is disposed at the other end of the SIP connector 12. The insertion parts 122 of respective SIP connectors 12 may be inserted into corresponding through holes 21 of a second circuit board 2 such that the first circuit board 11 and the second circuit board 2 are electrically connected to each other through the SIP connectors 12, as can be seen in FIG. 2.

Please refer to FIG. 1A again. The intermediate part 123 is disposed between the connecting part 121 and the insertion part 122. The cross-section area of the intermediate part 123 is greater than that of the insertion part 122. In addition, before the insertion part 122 of the SIP connector 12 is inserted into a corresponding through hole 21 of the second circuit board, the sheathing element 13 is sheathed around the insertion part 122 and supported by the intermediate part 123. The sheathing element 13 is preferably made of conductive and solderable material, e.g. metallic material. The cross-section area of the sheathing element 13 is greater than that of the intermediate part 123.

FIG. 1B is a schematic perspective view of a sheathing element shown in FIG. 1A. Please refer to FIG. 1B and also FIG. 1A. The sheathing element 13 includes a plurality of clamping arms 131, a receiving portion 132 and a plurality of degassing parts 133. The clamping arms 131 are discretely arranged at regular intervals along the circular periphery of the sheathing element 13 and extended in the axial direction of the sheathing element 13. The receiving portion 132 disposed in the middle of the sheathing element 13 is defined by the clamping arms 131. That is, the sheathing element 13 is substantially a conical structure with a central receiving portion 132. The cross-section area of the receiving portion 132 is substantially equal to or slightly greater than the outer diameter of the insertion part 122 of the connector 12. As a consequence, the receiving portion 132 of the sheathing element 13 may be sheathed around the insertion part 122, the clamping arms 131 are supported by the intermediate part 123, and the outer periphery of the insertion part 122 is clamped by the clamping arms 131. The degassing parts 133 are disposed between every two adjacent clamping arms 131. The degassing parts 133 may function as venting channels for venting gas during the soldering process, thereby minimizing formation of vacant space.

In an embodiment of the present invention, after the sheathing element 13 is sheathed around the insertion part 122 of the SIP connector 12 in the length direction, the clamping arms 131 of the sheathing element 13 are pressed by a jig tool (not shown) such that the conical structure is changed to a planar structure as shown in FIG 1C. As a consequence, the sheathing element 13 is securely fixed on the insertion part 122 of the SIP connector 12. In addition, since the clamping arms 131 of the sheathing element 13 are pressed to be coplanar, the distance between the insertion part 122 and each clamping arm 131 is shrunk. Meanwhile, the deformed clamping arms 131 may clamp and grip the insertion part 122 and thus the sheathing element 13 will be tight-fitted into the insertion part 122.

The circuit module 1 may be mounted on the second circuit board 2 by means of the SIP connector 12 and the sheathing element 13, thereby fabricating a circuit board assembly 3 as shown in FIG. 2. In an embodiment of the present invention, the circuit module 1 and the second circuit board 2 are a DC-to-DC converter module and a system board, respectively. The sidewalls of the through holes 21 of the second circuit board 2 have been coated with metallic material. In this embodiment, the cross-section area of the through hole 21 is smaller than that of the corresponding sheathing element 13 but is greater than or equal to that of the insertion part 122 of the corresponding SIP connector 12. After the SIP connectors 12 are mounted on the first circuit board 11 to result in the circuit module 1 shown in FIG. 1C, the insertion parts 122 of the SIP connectors 12 may be inserted into respective through holes 21 of the second circuit board 2 such that the sheathing elements 13 are sustained against the surface of the second circuit board 2. Since the cross-section area of the sheathing element 13 is greater than that of the intermediate part 123, the support area between the SIP connector 12 and the second circuit board 2 is increased.

Since the molten solder paste may be naturally filled in a gap between the insertion part 122 of the SIP connector 12, the sheathing element 13 and the through hole 21 of the second circuit board 2, the circuit module 1 may be securely fixed on the second circuit board 2. In addition, since the gas generated during the soldering process is vented through the degassing parts 133, the formation of vacant space is minimized, and the impedance and power loss are reduced. Via the SIP connectors 12, the electronic components 10 on the first circuit board 11 of the circuit module 1 are electrically connected to the electronic components 20 on the second circuit board 2, so that circuit board assembly 3 will be normally operated.

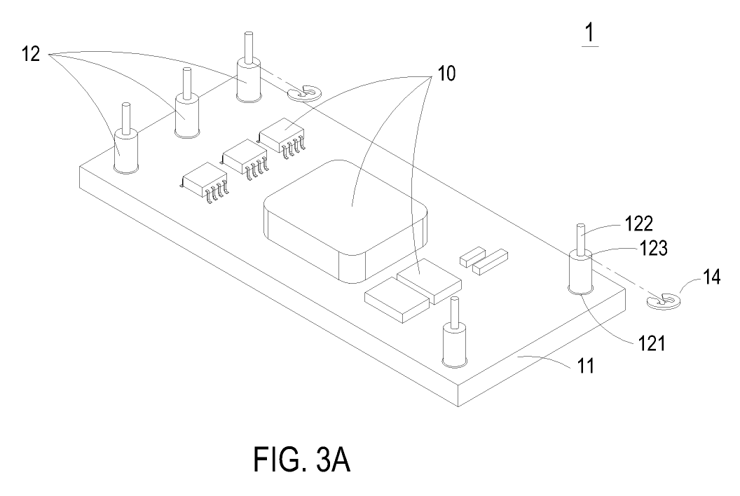

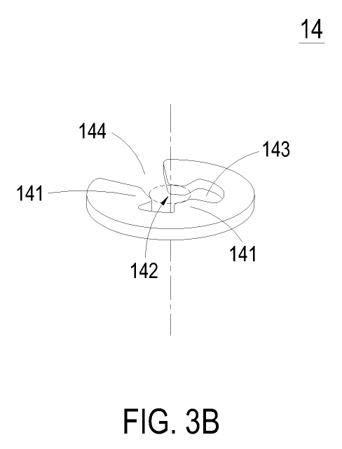

FIG. 3A is a schematic view illustrating a circuit module according to a second preferred embodiment of the present invention. As shown in FIG. 3A, the circuit module 1 principally includes a first circuit board 11, multiple SIP connectors 12 and multiple sheathing elements 14. The structures of the first circuit board 11 and the SIP connectors 12 are identical to those as shown in FIG. 1A, and are not redundantly described herein. FIG. 3B is a schematic perspective view of a sheathing element shown in FIG. 3A. Please refer to FIG. 3B and also FIG. 3A. The sheathing element 14 includes several (e.g. three) clamping arms 141, a receiving portion 142 and a plurality of degassing parts 143. The clamping arms 141 are discretely arranged at regular intervals along the circular periphery of the sheathing element 14 and extended in the axle center of the sheathing element 14. The receiving portion 142 disposed in the middle of the sheathing element 14 is defined by the clamping arms 141. In addition, the sheathing element 14 has a notch 144 which is communicated with the receiving portion 142. That is, the sheathing element 14 is substantially a ring-shaped structure with a central receiving portion 142 and the notch 144. The cross-section area of the receiving portion 142 is substantially equal to or slightly greater than the outer diameter of the insertion part 122 of the connector 12. As a consequence, the insertion part 122 may be received in the receiving portion 142 of the sheathing element 14 through the notch 144, the clamping arms 141 are supported by the intermediate part 123, and the outer periphery of the insertion part 122 is clamped by the clamping arms 141. The degassing parts 143 are disposed between every two adjacent clamping arms 141. The degassing parts 143 may function as venting channels for venting gas during the soldering process, thereby minimizing formation of vacant space. Since the cross-section area of the sheathing element 14 is greater than that of the intermediate part 123, the support area between the SIP connector 12 and the second circuit board 2 is increased.

Likewise, the circuit module 1 may be mounted on the second circuit board 2 by means of the SIP connector 12 and the sheathing element 14, thereby fabricating a circuit board assembly 3. After the SIP connectors 12 are mounted on the first circuit board 11 to result in the circuit module 1, the insertion parts 122 of the SIP connectors 12 may be inserted into respective through holes 21 of the second circuit board 2 such that the sheathing elements 14 are sustained against the surface of the second circuit board 2. Since the molten solder paste may be naturally filled in a gap between the insertion part 122 of the SIP connector 12, the sheathing element 14 and the through hole 21 of the second circuit board 2, the circuit module 1 may be securely fixed on the second circuit board 2. Via the SIP connectors 12, the electronic components 10 on the first circuit board 11 of the circuit module 1 are electrically connected to the electronic components 20 on the second circuit board 2, so that circuit board assembly 3 will be normally operated.

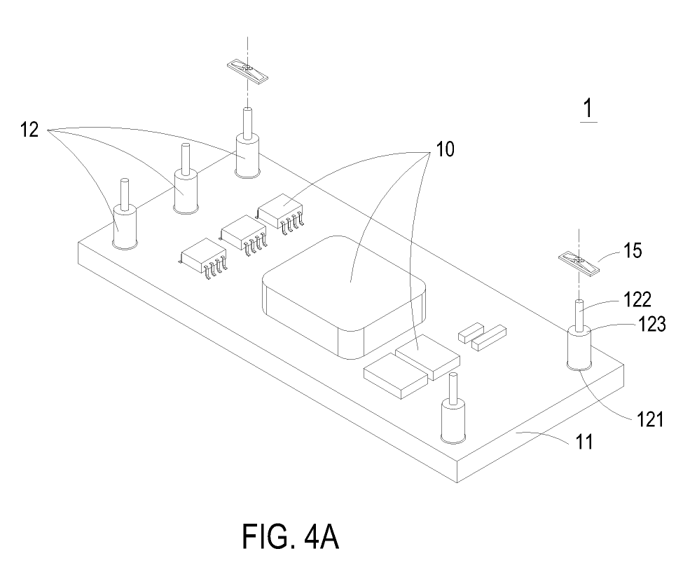

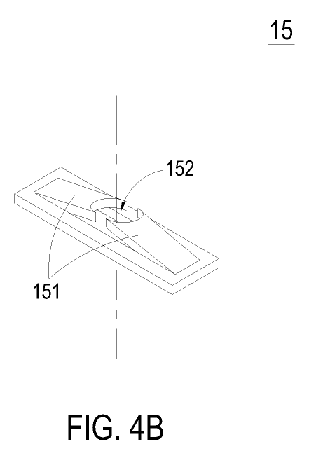

FIG. 4A is a schematic view illustrating a circuit module according to a third preferred embodiment of the present invention. As shown in FIG. 4A, the circuit module 1 principally includes a first circuit board 11, multiple SIP connectors 12 and multiple sheathing elements 15. The structures of the first circuit board 11 and the SIP connectors 12 are identical to those as shown in FIG. 1A, and are not redundantly described herein. FIG. 4B is a schematic perspective view of a sheathing element shown in FIG. 4A. Please refer to FIG. 4B and also FIG. 4A. The sheathing element 15 includes several (e.g. two) clamping arms 151 and a receiving portion 152. The sheathing element 15 is made by punching a metal plate. The receiving portion 152 disposed in the middle of the sheathing element 15 is defined by the clamping arms 151. The clamping arms 151 are slanted toward the receiving portion 152 such that the sheathing element 15 is a conical structure. In this embodiment, the sheathing element 15 has two clamping arms 151, which are disposed on opposite sides. The cross-section area of the receiving portion 152 is substantially equal to or slightly greater than the outer diameter of the insertion part 122 of the connector 12. As a consequence, the receiving portion 152 of the sheathing element 15 may be sheathed around the insertion part 122, the clamping arms 151 are supported by the intermediate part 123, and the outer periphery of the insertion part 122 is clamped by the clamping arms 151. After the sheathing element 15 is sheathed around the insertion part 122 of the SIP connector 12 in the length direction, the clamping arms 151 of the sheathing element 15 are pressed by a jig tool (not shown) such that the conical structure is changed to a planar structure. As a consequence, the sheathing element 15 is securely fixed on the insertion part 122 of the SIP connector 12.

From the above embodiments, since the cross-section area of the receiving portion 152 is substantially equal to or slightly greater than the outer diameter of the insertion part 122 of the connector 12, the receiving portion 152 of the sheathing element 15 is sheathed around the insertion part 122, the clamping arms 151 are supported by the intermediate part 123, and the outer periphery of the insertion part 121 is clamped by the clamping arms 151. Since the support area between the SIP connector 12 and the second circuit board 2 is increased, the first circuit board 11 and the second circuit board 2 will be parallel with each other and the first circuit board 11 is electrically connected to the second circuit board 2 via the SIP connectors 12.

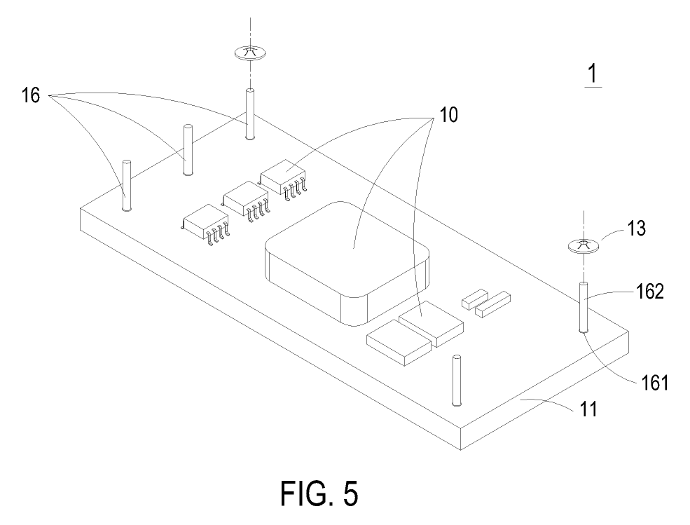

FIG. 5 is a schematic view illustrating a circuit module according to a fourth preferred embodiment of the present invention. As shown in FIG. 5, the circuit module 1 principally includes a first circuit board 11, multiple SIP connectors 16 and multiple sheathing elements 13. The structures of the first circuit board 11 and the sheathing elements 13 are identical to those as shown in FIG. 1A, and are not redundantly described herein. Each SIP connector 16 principally includes a connecting part 161 and an insertion part 162. The connecting part 161 is disposed at one end of the SIP connector 16 and fixed on the first circuit board 11. The insertion part 162 is disposed at the other end of the SIP connector 16. The cross-section area of the insertion part 162 is substantially identical to that of the connecting part 161. In other words, the SIP connector 16 is substantially a rod with uniform cross-section and preferably made of conductive material (e.g. metallic material).

After the sheathing element 13 is sheathed around the insertion part 162 of the SIP connector 16 in the length direction, the clamping arms 131 of the sheathing element 13 are pressed by a jig tool (not shown) such that the conical structure is changed to a planar structure. As a consequence, the sheathing element 13 is securely fixed on the insertion part 162 of the SIP connector 16. Since the SIP connector 16 is substantially a rod with uniform cross-section, the distance between the sheathing element 13 and the first circuit board 11 is adjustable. The deformed sheathing element 13 may clamp and grip the insertion part 162 and thus the sheathing element 13 will be tight-fitted into the insertion part 162. After all of the sheathing elements 13 are pressed to be coplanar, the circuit module 1 may be mounted on the second circuit board 2 by means of the SIP connector 16 and the sheathing element 13, thereby fabricating a circuit board assembly 3.

In the first, second and third embodiments shown in FIGS. 1A, 3A and 4A, the locations of the sheathing elements (13, 14 and 15) relative to the insertion parts (122) are also adjustable such that the height difference between the first circuit board and the second circuit board is substantially even.

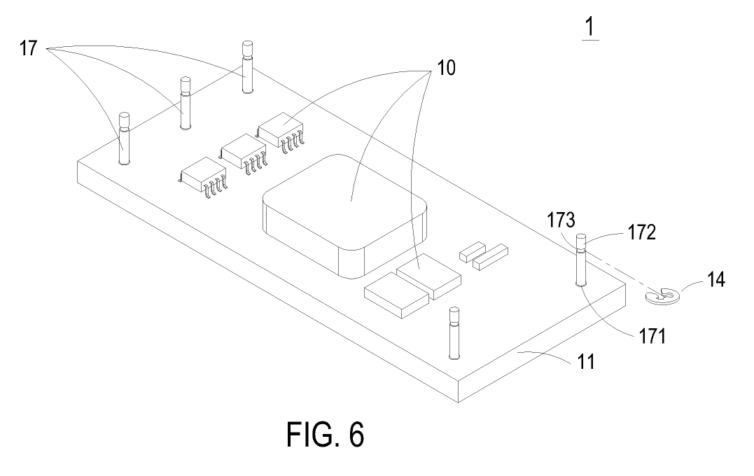

FIG. 6 is a schematic view illustrating a circuit module according to a fifth preferred embodiment of the present invention. As shown in FIG. 6, the circuit module 1 principally includes a first circuit board 11, multiple SIP connectors 17 and multiple sheathing elements 14. The structures of the first circuit board 11 and the sheathing elements 14 are identical to those as shown in FIGS. 3A and 3B, and are not redundantly described herein. Each SIP connector 17 principally includes a connecting part 171 and an insertion part 172. The connecting part 171 is disposed at one end of the SIP connector 17 and fixed on the first circuit board 11. The insertion part 172 is disposed at the other end of the SIP connector 17. The cross-section area of the insertion part 172 is substantially identical to that of the connecting part 171. In other words, the SIP connector 17 is substantially a rod with uniform cross-section. Moreover, the connecting part 171 further includes a recess 173, which is disposed between the connecting part 171 and the insertion part 172 in circular arrangement. In this embodiment, the insertion part 172 may be received in the receiving portion 142 of the sheathing element 14 through the notch 144 such that the sheathing element 14 is fixed in the recess 173.

Alternatively, the SIP connector 17 may have one or more recesses 173. The locations of the recesses 173 are preset according to the requisite distance between the first circuit board 11 and the second circuit board 2. For example, if the distance between the first circuit board 11 and the second circuit board 2 is shrunk, the sheathing element 14 is fixed in the recess 173 which is located in the vicinity of the connecting part 171. On the contrary, if the distance between the first circuit board 11 and the second circuit board 2 is extended, the sheathing element 14 is fixed in the recess 173 which is located in the vicinity of the insertion part 172. Therefore, the height of the circuit board assembly is adjusted according to the manufacturer's requirement.

Alternatively, the sheathing element 15 as shown in FIG. 4B may be sheathed around the SIP connector 16 of FIG. 5 or the SIP connector 17 of FIG. 6. In other words, one of the sheathing elements 13 and 15 may pair with one of the SIP connectors 12, 16 and 17 to implement many variations.

From the above description, the insertion part of a SIP connector is received in a receiving portion defined by the clamping arms of a corresponding sheathing element and clamped by the clamping arms, so that the sheathing element is securely fixed on the SIP connector. In addition, since the cross-section area of the sheathing element is greater than that of the SIP connector, the sheathing element may be sustained against the surface of the system board after the insertion part of the SIP connector is inserted into a corresponding through hole of the system board. Even if the diameter of the through hole is greater than that of the insertion part, the sheathing element may be sustained against the surface of the system board such that the SIP connector is securely fixed on the system board.

Moreover, even if the diameter of the through hole in the system board is changed, the SIP connector can be sustained against the surface of the system board in the assistance of the sheathing element. In other words, the SIP connector may be acted as a general-purpose connector without the need of changing the cross-section area thereof. Therefore, the fabricating process the SIP connector of the prevent invention is simplified and the fabricating cost is reduced.

By pairing a sheathing element with of the SIP connector, the support area between the SIP connector and the system board is increased and the electrical connection and the structural stability between the first circuit board and the system board are enhanced. Moreover, the degassing parts may function as venting channels for venting gas during the soldering process, thereby minimizing formation of vacant space.

Moreover, since the distance between the circuit module and the system board may be varied by changing the location of the sheathing element relative to the SIP connector, the height of the circuit board assembly is adjustable. By adjusting the sheathing element to be coplanar, the height difference between the first circuit board and the second circuit board will be substantially even and thus the first circuit board and the second circuit board will be parallel with each other.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A circuit module to be mounted on a system board having multiple through holes, said circuit module comprising:
a circuit board;
multiple SIP connectors, each of which includes a connecting part disposed at a first end thereof and fixed on said circuit board and an insertion part disposed at a second end thereof, and
multiple sheathing elements, each of which includes a plurality of clamping arms and a receiving portion, wherein said receiving portion is defined by said clamping arms for receiving said insertion part of a corresponding SIP connector, and said insertion part is clamped by said clamping arms such that said sheathing element is fixed on said SIP connector, wherein said sheathing element is sustained against a surface of said system board after said insertion part is inserted into a corresponding through hole of said system board, so that the support area between said SIP connector and said system board is increased.

2. The circuit module according to claim 1 wherein said clamping arms are extended in an axial direction of said sheathing element such that said sheathing element is substantially a conical structure with said receiving portion, and said sheathing element is tight-fitted into said insertion part in response to deformation of said clamping arms.

3. The circuit module according to claim 1 wherein said sheathing element further includes a notch communicated with said receiving portion such that said insertion part is received in said receiving portion through said notch.

4. The circuit module according to claim 1 wherein said sheathing element further includes one or more degassing parts, which is disposed between every two adjacent clamping arms.

5. The circuit module according to claim 1 wherein said SIP connector further includes an intermediate part between said connecting part and said insertion part, and said sheathing element is sheathed around said insertion part and supported by said intermediate part.

6. The circuit module according to claim 1 wherein said SIP connector further includes a recess between said connecting part and said insertion part, and said sheathing element is sheathed around said recess.

7. The circuit module according to claim 1 wherein said SIP connector is substantially a rod with uniform cross-section.

8. The circuit module according to claim 1 wherein the cross-section area of said sheathing element is greater than that of said SIP connector.

9. A circuit board assembly comprising:
a first circuit board;
a second circuit board having a plurality of through holes; and
multiple SIP connectors arranged between said first circuit board and said second circuit board, each SIP connector comprising a connecting part disposed at a first end thereof and fixed on said first circuit board and an insertion part disposed at a second end thereof; and
multiple sheathing elements, each of which includes a plurality of clamping arms and a receiving portion, wherein said receiving portion is defined by said clamping arms for receiving said insertion part of a corresponding SIP connector, and said insertion part is clamped by said clamping arms such that said sheathing element is fixed on said SIP connector, wherein said sheathing element is sustained against a surface of said second circuit board after said insertion part is inserted into a corresponding through hole of said second circuit board, so that the support area between said SIP connector and said second circuit board is increased and said first circuit board is electrically and structurally connected with said second circuit board via said SIP connector.

10. The circuit board assembly according to claim 9 wherein said clamping arms are extended in an axial direction of said sheathing element such that said sheathing element is substantially a conical structure with said receiving portion, and said sheathing element is tight-fitted into said insertion part in response to deformation of said clamping arms.

11. The circuit board assembly according to claim 9 wherein said sheathing element further includes a notch communicated with said receiving portion such that said insertion part is received in said receiving portion through said notch.

12. The circuit board assembly according to claim 9 wherein said sheathing element further includes one or more degassing parts, which is disposed between every two adjacent clamping arms.

13. The circuit board assembly according to claim 9 wherein said SIP connector further includes an intermediate part between said connecting part and said insertion part, and said sheathing element is sheathed around said insertion part and supported by said intermediate part.

14. The circuit board assembly according to claim 9 wherein said SIP connector further includes a recess between said connecting part and said insertion part, and said sheathing element is sheathed around said recess.

15. The circuit board assembly according to claim 9 wherein said SIP connector is substantially a rod with uniform cross-section.

16. The circuit board assembly according to claim 9 wherein the cross-section area of said sheathing element is greater than that of said SIP connector.

17. A sheathing element to be sheathed around a SIP connector, said SIP connector being inserted into a through hole of a circuit board, said sheathing element comprising:
a plurality of clamping arms; and
a receiving portion defined by said clamping arms for receiving said SIP connector, wherein said sheathing element is sustained against a surface of said circuit board after an insertion part of said SIP connector is inserted into said through hole of said circuit board, so that the support area between said SIP connector and said circuit board is increased.

18. The sheathing element according to claim 17 wherein said clamping arms are extended in an axial direction of said sheathing element such that said sheathing element is substantially a conical structure with said receiving portion, and said sheathing element is tight-fitted into said insertion part in response to deformation of said clamping arms.

19. The sheathing element according to claim 17 wherein said sheathing element further includes a notch communicated with said receiving portion such that said insertion part is received in said receiving portion through said notch.

20. The sheathing element according to claim 17 wherein said sheathing element further includes one or more degassing parts between every two adjacent clamping arms, and the cross-section area of said sheathing element is greater than that of said SIP connector.
